(19) United States
(12) Patent Application Publication
(10) Pub. No.: US 2026/0214818 A1
(43) Pub. Date: Jul. 23, 2026

(54) LIGHT AND THIN SPLITTER

(71) Applicant: Gongjun Xia, Anhui Province (CN)

(72) Inventor: Gongjun Xia, Anhui Province (CN)

(21) Appl. No.: 19/053,894

(22) Filed: Feb. 14, 2025

(30) Foreign Application Priority Data
Jan. 20, 2025 (CN) 202510087415.5

(51) Int. Cl. H05K 5/02; H05K 5/30

(52) U.S. Cl. CPC H05K 5/0217; H05K 5/0204; H05K 5/30

(57) ABSTRACT

The present disclosure relates to a light and thin splitter, including a connecting plate and a screen. The connecting plate includes a main plate and an accessory plate. The main plate is rotatably connected to the screen, and the accessory plate is transversely provided in the middle of the main plate. The thickness of the screen is not greater than 6.5 MM, the sum of the thickness of the screen and the thickness of the accessory plate is not greater than 15 MM, and the sum of the thickness of the screen and the thickness of the connecting plate is not greater than 21 MM. A first groove is provided in the front of the connecting plate, a clamping part is provided in the first groove, the clamping part is rotatably provided in the first groove, and a maximum included angle of the clamping part formed relative to the connecting plate ranges from 20° to 80°. By implementing the above technical solution, the light and thin splitter has the following technical effects: the light and thin splitter is light and thin, convenient to use, reliable in performance and good in experience feeling, and provides the best usage experience to a user when solving the problem of inconvenient trip as the user carries the splitter.

### CROSS REFERENCE TO RELATED APPLICATION

This application claims priority benefit of Chinese patent Application No. 202510087415.5, filed on Jan. 20, 2025, and the entire contents of which are incorporated herein by reference.

### BACKGROUND OF THE INVENTION

### 1. Technical Field

The present disclosure relates to the technical field of splitters, and particularly relates to a light and thin splitter.

### 2. Description of Related Art

Existing double-screen splitters on the current market are heavy and large in size after being folded. In actual use, the double-screen splitters are inconvenient to carry and poor in experience feeling.

### BRIEF SUMMARY OF THE INVENTION

The present disclosure provides a light and thin splitter, which solves the problem of existing splitters.

In order to achieve the above objective, the present disclosure provides the following technical solution: a light and thin splitter, including a connecting plate 100 and a screen 200, wherein the connecting plate 100 includes a main plate 101 and an accessory plate 102, the main plate 101 is communicated with an inside of the screen 200 through the rotating shaft, the main plate 101 is electrically connected to the screen 200, the accessory plate 102 is transversely provided in a middle of the main plate 101, the connecting plate 100 includes a first stretching part and a second stretching part, the first stretching part is in stretchably connected to the second stretching part through a stretching plate 108, a fourth groove 118 is provided in a back of the connecting plate 100, and a first bracket 120 is rotatably provided in the fourth groove 118; a thickness of the screen 200 is not greater than 6.5 MM, the sum of the thickness of the screen 200 and a thickness of the main plate 101 is not greater than 15 MM, and the sum of the thickness of the screen 200 and a thickness of the connecting plate 100 is not greater than 21 MM; and a first groove 103 is provided in a front of the connecting plate 100, a clamping part 104 is rotatably provided in the first groove 103, and a maximum included angle of the clamping part 104 formed relative to the connecting plate 100 ranges from 20° to 80°.

Preferably, the clamping part 104 is rotatably provided in the first groove 103 through a limiting spring 125, and the maximum included angle of the clamping part 104 formed relative to the connecting plate 100 ranges from 50° to 80°.

Preferably, the thickness of the screen 200 is not greater than 4.5 MM, the thickness of the connecting plate 100 is not greater than 10 MM, and the sum of the thickness of the main plate 101 and the thickness of the screen 200 is not greater than 12.46 MM.

Preferably, the screen 200 includes a first display screen 201 and a second display screen 202, the first display screen 201 is rotatably provided on a left side of the main plate 101, the second display screen 202 is rotatably provided on a right side of the main plate 101, the sum of the thickness of the connecting plate 100, the thickness of the first display screen 201, and the thickness of the second display screen 202 is not greater than 20.4 MM, and the sum of masses of the connecting plate 100, the first display screen 201, and the second display screen 202 is not greater than 1.1 KG.

Preferably, the main plate 101 includes a first part 105 and a second part 106, the accessory plate 102 includes a third part 107 and a fourth part 107, the first part 105 and the third part 107 form a first stretching part, the second part 106 and the fourth part 107 form a second stretching part, and the first stretching part is stretchably connected to the second stretching part.

Preferably, the second part 106 includes a stretching plate 108, the first part 105 is provided with a second groove 109 rightward, a clockwork spring 110 is provided in the second groove 109 or on a left side of the second groove 109, and the clockwork spring 110 is connected to the stretching plate 108.

Preferably, the second part 106 is internally provided with a third groove 111, the third groove 111 is internally provided with a circuit board, and the circuit board is electrically connected to the first display screen 201 and the second display screen 202; the stretching plate 108 is internally provided with a wiring channel 112, a first shaft 113 is provided on a left side of the connecting plate 100, the connecting plate 100 is rotatably connected to the first display screen 201 through the first shaft 113, the first shaft 113 is internally provided with a first through-hole 114, the third groove 111 is communicated with the wiring channel 112, the wiring channel 112 is communicated with the first through-hole 114, and the first through-hole 114 is communicated with an interior of the first display screen 201; and a second shaft 115 is provided on a right side of the connecting plate 100, the connecting plate 100 is rotatably connected to the second display screen 202 through the second shaft 115, the second shaft 115 is internally provided with a second through-hole 116, the third groove 111 is communicated with the second through-hole 116, and the second through-hole 116 is communicated with an interior of the second display screen 202.

Preferably, hooks 117 are provided forward on the first part 105 and the second part 106.

Preferably, a fourth groove 118 is provided in a back of the third part 107, a fifth groove 119 corresponding to the fourth groove 118 is provided in a back of the fourth part 107, and a first bracket 120 is rotatably provided in the fourth groove 118 and the fifth groove 119.

Preferably, the light and thin splitter includes a second bracket 121, wherein the second bracket 121 is provided with a sixth groove 122, the first bracket 120 is stretchably provided in the sixth groove 122, and the first bracket 120 is provided with a silica gel 123 and a silicon steel limiting block 124.

By implementing the above technical solution, the light and thin splitter has the following technical effects: the light and thin splitter is light and thin, convenient to use, reliable in performance and good in experience feeling, and provides the best usage experience to a user when solving the problem of inconvenient trip as the user carries the splitter.

### BRIEF DESCRIPTION OF THE SEVERAL VIEWS OF THE DRAWINGS

FIG. 1 is an overall schematic structural diagram (stereogram) of a light and thin splitter according to the present disclosure;

FIG. 2 is an overall schematic structural diagram (stereogram) of a light and thin splitter according to the present disclosure;

FIG. 3 is a partial schematic structural diagram (stereogram) of a light and thin splitter according to the present disclosure;

FIG. 4 is a partial schematic structural diagram (stereogram) of a light and thin splitter according to the present disclosure;

FIG. 5 is a partial schematic structural diagram (stereogram) of a light and thin splitter according to the present disclosure;

FIG. 6 is an overall schematic structural diagram (stereogram) of a light and thin splitter according to the present disclosure;

FIG. 7 is an overall schematic structural diagram (stereogram) of a light and thin splitter in a folded state according to the present disclosure;

FIG. 8 is an overall schematic structural diagram (stereogram) of a light and thin splitter in a folded state according to the present disclosure; and

FIG. 9 is a partial schematic structural diagram (stereogram) of a light and thin splitter in a folded state according to the present disclosure.

### DETAILED DESCRIPTION OF THE INVENTION

To better understand the technical solution of the present disclosure, the embodiments provided by the present disclosure will be described in detail below in conjunction with drawings.

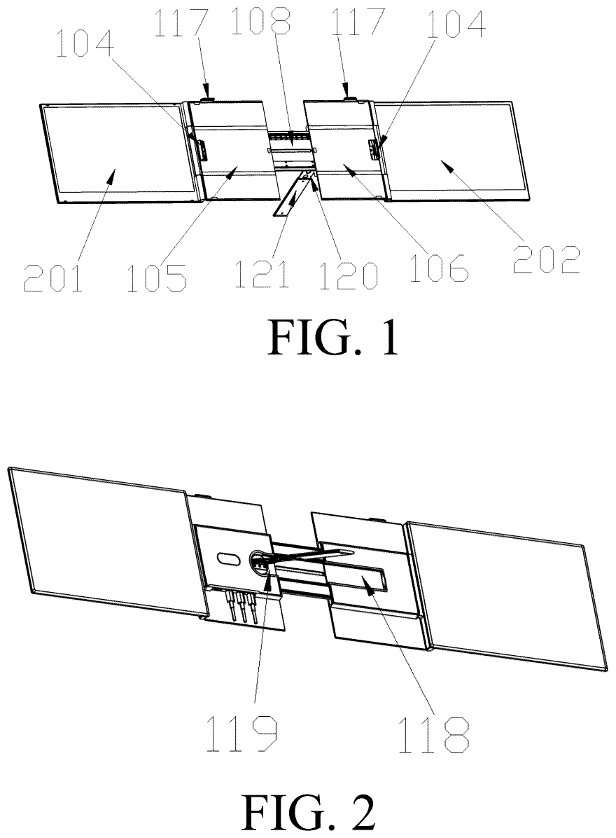

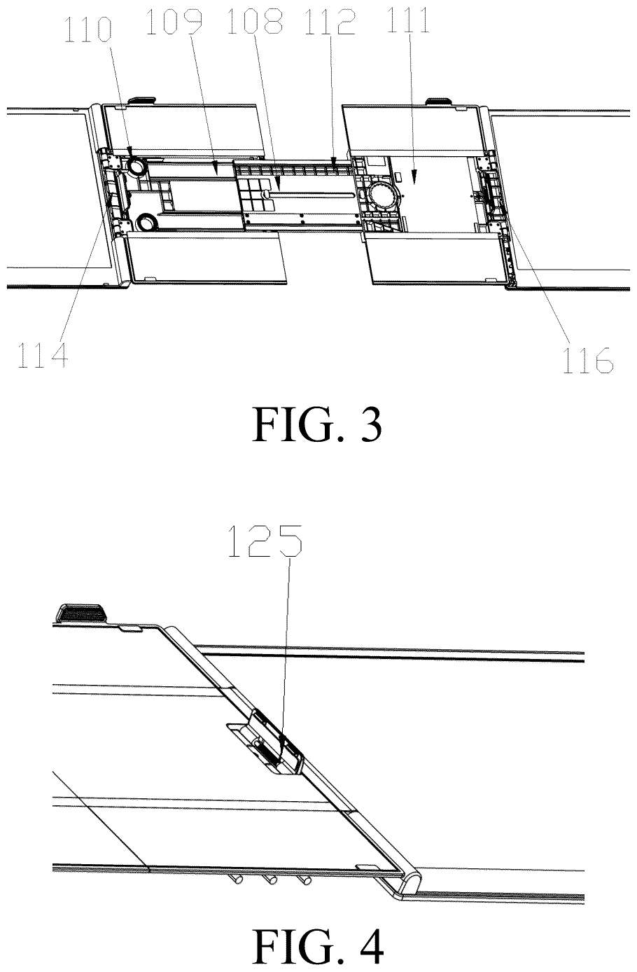

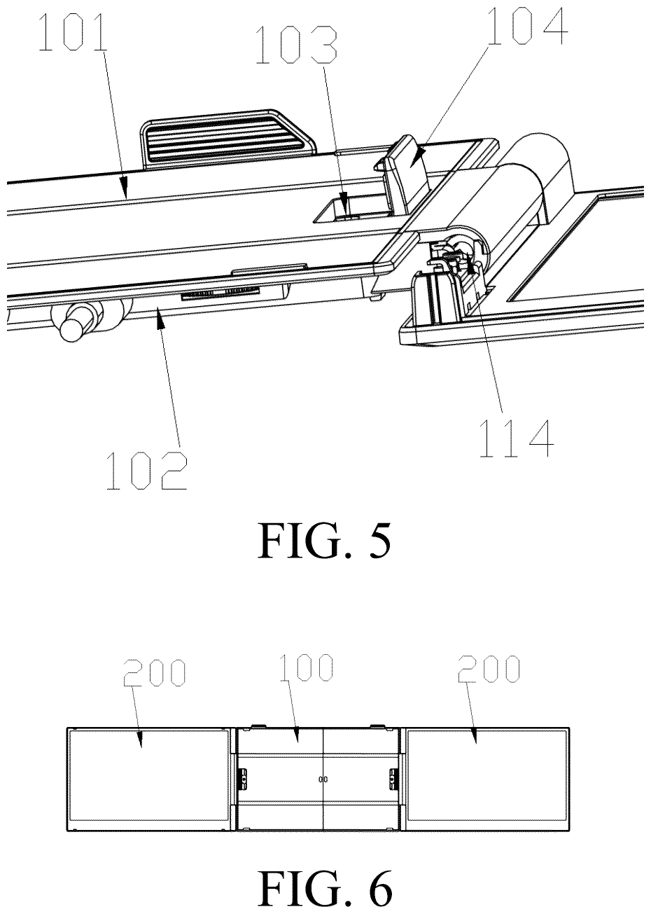

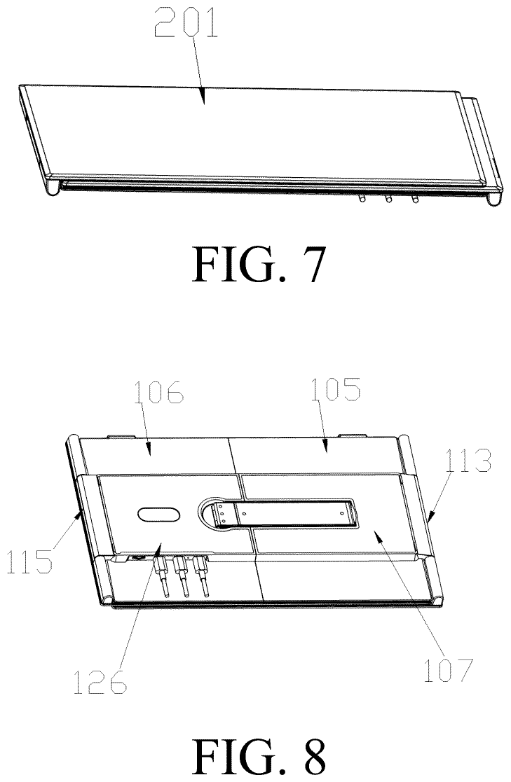

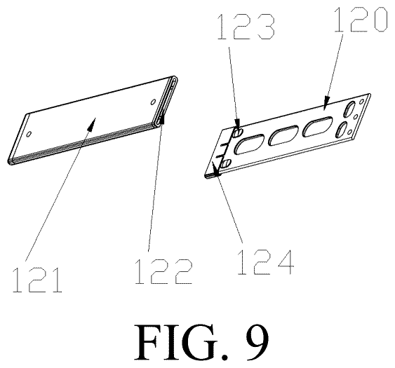

As shown in FIGS. 1-9, it may be understood that the embodiment provides a light and thin splitter, including a connecting plate 100 and a screen 200, wherein the connecting plate 100 includes a main plate 101 and an accessory plate 102, the main plate 101 is rotatably connected to the screen 200 through a rotating shaft, the main plate 101 is communicated with the inside of the screen 200 through the rotating shaft, and the main plate 101 is electrically connected to the screen 200, so that the main plate 101 and the screen 200 may be electrically connected through the rotating shaft via an electric wire, the electric wire is hidden while a power supply function is realized, and it is beautiful and convenient; the accessory plate 102 is transversely provided in the middle of the main plate 101, the connecting plate 100 includes a first stretching part and a second stretching part, the first stretching part is in stretchably connected to the second stretching part through a stretching plate 108, so that the edge of the connecting plate 100 is thinner for the convenience of grabbing, and it is convenient to clamp electronic devices with different sizes for use in a matched manner; a fourth groove 118 is provided in the back of the connecting plate 100, and a first bracket 120 is rotatably provided in the fourth groove 118, so that when the first bracket 120 is folded, the upper surface of the first bracket 120 is horizontal to or lower than the upper surface of the back of the connecting plate 100, thus hiding the bracket and minimizing the thickness of the product; during use, it only needs to lift up the first bracket 120 and rotate the first bracket to a use angle, so that the splitter can be supported when used independently; the thickness of the screen 200 is not greater than 6.5 MM, and the screen 200 is made of an alloy and a plastic, so that the screen 200 is thinner; the sum of the thickness of the screen 200 and the thickness of the accessory plate 102 is not greater than 15 MM, and the sum of the thickness of the screen 200 and the thickness of the connecting plate 100 is not greater than 21 MM, and after the screen is rotated relative to the connecting plate 100 to be close to the front of the connecting plate 100, the splitter as a whole is thinner relative to other splitters, so that it is convenient for a user to grab the edge of the main plate of the folded splitter to fold the splitter; a first groove 103 is provided in the front of the connecting plate 100, a clamping part 104 is rotatably provided in the first groove 103, and the maximum included angle of the clamping part 104 formed relative to the connecting plate 100 ranges from 20° to 80°; when the screen 200 is unfolded and the screen 200 is folded, the screen 200 presses the clamping part 104 to press the clamping part 104 in the first groove 103 to achieve folding; due to the maximum unfolding angle of 20° to 80°, when the screen 200 presses the clamping part 104, the screen is not damaged; and during use, the screen 200 is unfolded, other electronic devices are clamped in the clamping part 104, so that it is convenient to fix the splitter and other electronic products, and therefore, the usage experience is improved.

In embodiment II, the clamping part 104 is rotatably provided in the first groove 103 through a limiting spring 125, and the maximum included angle of the clamping part 104 formed relative to the connecting plate 100 ranges from 50° to 80°, so that on the premise that the clamping part 104 is capable of clamping other electronic devices to the maximum extent, when the screen 200 presses the clamping part 104, the screen is prevented from being extruded and damaged by the clamping part 104 to a greater extent. Preferably, when the maximum included angle is 65°, the clamping part 104 can be conveniently folded to the maximum extent, and the screen can also be prevented from being extruded and damaged, so that the service life of the product is prolonged.

In embodiment II, the upper surface and the left side surface of the clamping part 104 are preferably convex arc-shaped, and the radian of the left side surface is preferably greater than the radian of the upper surface, so that when the screen 200 presses the clamping part 104, the screen is prevented from being extruded and damaged by the clamping part 104 to the maximum extent, and the durability of the product is improved.

Based on the above embodiments, further, the thickness of the screen 200 is not greater than 5 MM, the thickness of the connecting plate 100 is not greater than 10 MM, and the sum of the thickness of the main plate 101 and the thickness of the screen 200 is not greater than 13 MM. The screen 200, the connecting plate 100, and the folded splitter are thinner, so that it is more convenient for the user to grab the edge of the main plate of the unfolded or folded splitter to fold the splitter, and the usage experience of the user is further improved.

Based on the above embodiments, further, the screen 200 includes a first display screen 201 and a second display screen 202, the first display screen 201 is rotatably provided on the left side of the main plate 101, the second display screen 202 is rotatably provided on the right side of the main plate 101, the sum of the thickness of the connecting plate 100, the thickness of the first display screen 201, and the thickness of the second display screen 202 is not greater than 20.4 MM, and the sum of masses of the connecting plate 100, the first display screen 201, and the second display screen 202 is not greater than 1.1 KG. By rotating the first display screen 201 and the second display screen 202, the first display screen and the second display screen are rotated to the front of the main plate 101 to be folded. The total thickness of the folded splitter does not exceed 20.4 MM and the total mass is not greater than 1.1 KG. At this proportion, the product is light and thin while the structural strength is ensured, so that the usage experience of the user is further improved.

Based on the above embodiments, further, the main plate 101 includes a first part 105 and a second part 106, the accessory plate 102 includes a third part 107 and a fourth part 107, the first part 105 and the third part 107 form a first stretching part, the second part 106 and the fourth part 107 form a second stretching part, and the first stretching part is stretchably connected to the second stretching part, so that the function of prolonging the main plate 101 is realized. It is convenient for the user to fix the main plate 101 to a length to match with other electronic devices, and when not used, the main plate 101 is fixed to the minimum length, so that it is convenient to fold.

Based on the above embodiments, further, the second part 106 includes a stretching plate 108, the first part 105 is provided with a second groove 109 rightward, a clockwork spring 110 is provided in the second groove 109 or on the left side of the second groove 109, and the clockwork spring 110 is connected to the stretching plate 108. The clockwork spring 110 will provide a sustained tensile force to the stretching plate 108 so as to provide a sustained tensile force between the first part 105 and the second part 106. When it is pulled to be unfolded for use, the first part 105 and the second part 106 are conveniently fixed to other electronic products. When not used, the tensile force provided by the clockwork spring 110 to the stretching plate 108 may tightly fix the two together, so that the stability of the product in the folded state is improved; in addition, the settable depth of the stretching plate 108 may be improved by changing the position of the clockwork spring, so that the maximum length of the main plate 101 is increased, the range of the product matching with other electronic products in use is further expanded, and the adaptability of the product is improved.

Based on the above embodiments, further, the second part 106 is internally provided with a third groove 111, the third groove 111 is internally provided with a circuit board, and the circuit board is electrically connected to the first display screen 201 and the second display screen 202; the stretching plate 108 is internally provided with a wiring channel 112, a first shaft 113 is provided on the left side of the connecting plate 100, the connecting plate 100 is rotatably connected to the first display screen 201 through the first shaft 113, the first shaft 113 is internally provided with a first through-hole 114, the third groove 111 is communicated with the wiring channel 112, the wiring channel 112 is communicated with the first through-hole 114, and the first through-hole 114 is communicated with the interior of the first display screen 201; and a second shaft 115 is provided on the right side of the connecting plate 100, the connecting plate 100 is rotatably connected to the second display screen 202 through the second shaft 115, the second shaft 115 is internally provided with a second through-hole 116, the third groove 111 is communicated with the second through-hole 116, and the second through-hole 116 is communicated with the interior of the second display screen 202. A wire is led from the circuit board to pass through the third groove 111, the wiring channel 112, and the first through-hole 114 in sequence and is connected to the interior of the first display screen 201 and a wire is led from the circuit board to pass through the third groove 111 and the second through-hole 116 in sequence and is connected to the interior of the second display screen 202, so that on the premise of hidden wiring, the circuit board and the screen are electrically connected. The appearance is beautiful and wiring is regular to facilitate use.

Based on the above embodiments, further, hooks 117 are provided forward on the first part 105 and the second part 106. The hooks 117 may be hooked on a computer or other electronic products, so that the splitter is closer to the screen of the computer. It is convenient for the user to see different screens at the same time, so that the usage experience of the user is improved.

Based on the above embodiments, further, a fourth groove 118 is provided in the back of the third part 107, a fifth groove 119 corresponding to the fourth groove 118 is provided in the back of the fourth part 107, and a first bracket 120 is rotatably provided in the fourth groove 118 and the fifth groove 119, so that when the first bracket 120 is folded, the upper surface of the first bracket 120 is horizontal to or lower than the upper surface of the back of the fourth part 107, a longer hidden bracket may be used, and the product has the minimum thickness and a greater length; and during use, it only needs to lift up the first bracket 120 and rotate the first bracket to a use angle, so that the splitter can be supported when used independently, and the usage experience of the user is improved.

Based on the above embodiments, further, the light and thin splitter includes a second bracket 121, wherein the second bracket 121 is provided with a sixth groove 122, the first bracket 120 is stretchably provided in the sixth groove 122, and the first bracket 120 is provided with a silica gel 123 and a silicon steel limiting block 124. When the splitter is placed on a desktop to be used independently, the second bracket 121 may stretch relative to the first bracket 120, so that the total length of the bracket is prolonged, and it is convenient for the user to select different supporting angles; the silica gel 123 may provide frictional resistance between the first bracket 120 and the second bracket 121, so that it is convenient for the user to stop at different lengths, and the silicon steel limiting block 124 is used to prevent excessive friction between the first bracket 120 and the second bracket 121.

The light and thin splitter provided by the embodiment of the present disclosure is introduced in detail above. For those skilled in the art, there will be changes in the specific implementation mode and the application scope according to the idea of the embodiment of the present disclosure. In conclusion, the content of the specification shall not be construed as a limitation to the present disclosure.

What is claimed is:

1. A light and thin splitter, comprising a connecting plate (100) and a screen (200), wherein the connecting plate (100) comprises a main plate (101) and an accessory plate (102), the main plate (101) is rotatably connected to the screen (200) through a rotating shaft, the main plate (101) is communicated with an inside of the screen (200) through the rotating shaft, the main plate (101) is electrically connected to the screen (200), the accessory plate (102) is transversely provided in a middle of the main plate (101), the connecting plate (100) comprises a first stretching part and a second stretching part, the first stretching part is in stretchably connected to the second stretching part through a stretching plate (108), a fourth groove (118) is provided in a back of the connecting plate (100), and a first bracket (120) is rotatably provided in the fourth groove (118);
a thickness of the screen (200) is not greater than 6.5 MM, the sum of the thickness of the screen (200) and a thickness of the main plate (101) is not greater than 15 MM, and the sum of the thickness of the screen (200) and a thickness of the connecting plate (100) is not greater than 21 MM; and
a first groove (103) is provided in a front of the connecting plate (100), a clamping part (104) is rotatably provided in the first groove (103), and a maximum included angle of the clamping part (104) formed relative to the connecting plate (100) ranges from 20° to 80°.

2. The light and thin splitter according to claim 1, wherein the clamping part (104) is rotatably provided in the first groove (103) through a limiting spring (125), and the maximum included angle of the clamping part (104) formed relative to the connecting plate (100) ranges from 50° to 80°.

3. The light and thin splitter according to claim 1, wherein the thickness of the screen (200) is not greater than 5 MM, the thickness of the connecting plate (100) is not greater than 10 MM, and the sum of the thickness of the main plate (101) and the thickness of the screen (200) is not greater than 13 MM.

4. The light and thin splitter according to claim 3, wherein the screen (200) comprises a first display screen (201) and a second display screen (202), the first display screen (201) is rotatably provided on a left side of the main plate (101), the second display screen (202) is rotatably provided on a right side of the main plate (101), the sum of the thickness of the connecting plate (100), a thickness of the first display screen (201), and a thickness of the second display screen (202) is not greater than 20.4 MM, and the sum of masses of the connecting plate (100), the first display screen (201), and the second display screen (202) is not greater than 1.1 KG.

5. The light and thin splitter according to claim 4, wherein the main plate (101) comprises a first part (105) and a second part (106), the accessory plate (102) comprises a third part (107) and a fourth part (107), the first part (105) and the third part (107) form a first stretching part, the second part (106) and the fourth part (107) form a second stretching part, and the first stretching part is stretchably connected to the second stretching part.

6. The light and thin splitter according to claim 5, wherein the second part (106) comprises a stretching plate (108), the first part (105) is provided with a second groove (109) rightward, a clockwork spring (110) is provided in the second groove (109) or on a left side of the second groove (109), and the clockwork spring (110) is connected to the stretching plate (108).

7. The light and thin splitter according to claim 5, wherein the second part (106) is internally provided with a third groove (111), the third groove (111) is internally provided with a circuit board, and the circuit board is electrically connected to the first display screen (201) and the second display screen (202);
the stretching plate (108) is internally provided with a wiring channel (112), a first shaft (113) is provided on a left side of the connecting plate (100), the connecting plate (100) is rotatably connected to the first display screen (201) through the first shaft (113), the first shaft (113) is internally provided with a first through-hole (114), the third groove (111) is communicated with the wiring channel (112), the wiring channel (112) is communicated with the first through-hole (114), and the first through-hole (114) is communicated with an interior of the first display screen (201); and
a second shaft (115) is provided on a right side of the connecting plate (100), the connecting plate (100) is rotatably connected to the second display screen (202) through the second shaft (115), the second shaft (115) is internally provided with a second through-hole (116), the third groove (111) is communicated with the second through-hole (116), and the second through-hole (116) is communicated with an interior of the second display screen (202).

8. The light and thin splitter according to claim 5, wherein hooks (117) are provided forward on the first part (105) and the second part (106).

9. The light and thin splitter according to claim 5, wherein a fourth groove (118) is provided in a back of the third part (107), a fifth groove (119) corresponding to the fourth groove (118) is provided in a back of the fourth part (107), and a first bracket (120) is rotatably provided in the fourth groove (118) and the fifth groove (119).

10. The light and thin splitter according to claim 9, comprising a second bracket (121), wherein the second bracket (121) is provided with a sixth groove (122), the first bracket (120) is stretchably provided in the sixth groove (122), and the first bracket (120) is provided with a silica gel (123) and a silicon steel limiting block (124).
